(19) United States
(12) Patent Application Publication
(10) Pub. No.: US 2015/0318385 A1
(43) Pub. Date: Nov. 5, 2015

(54) SEMICONDUCTOR DEVICE

(71) Applicant: Satoru KAMEYAMA, (US)

(72) Inventor: Satoru KAMEYAMA, Toyota-shi (JP)

(73) Assignee: TOYOTA JIDOSHA KABUSHIKI KAISHA, Toyota-shi, Aichi-ken (JP)

(21) Appl. No.: 14/443,509

(22) PCT Filed: Dec. 5, 2012
(86) PCT No.: PCT/JP2012/081483

§ 371 Date: May 18, 2015

(51) Int. Cl. H01L 29/739; H01L 29/10; H01L 29/861; H01L 27/06; H01L 29/872; H01L 29/36

(52) U.S. Cl. CPC H01L 29/7395; H01L 29/872; H01L 29/36; H01L 29/861; H01L 27/0629; H01L 29/1095

(57) ABSTRACT

A first semiconductor device presented by the specification includes a semiconductor substrate that includes an anode region and a cathode region. The anode region includes a first conductivity type first region having a maximum impurity concentration of the first conductivity type at a position that is at a first depth from a surface of the semiconductor substrate and a first conductivity type second region having a maximum impurity concentration of the first conductivity type at a position that is at a second depth, and on a surface side of the semiconductor substrate than the first depth, and a third region provided between the first region and the second region, and having an impurity concentration of the first conductivity type that is equal to or less than 1/10 (one-tenth) of a impurity concentration of the surface of the semiconductor substrate.

### TECHNICAL FIELD

A technique described in the specification relates to a semiconductor device.

### BACKGROUND ART

In a semiconductor device having a diode element structure, a design of an anode region affects properties such as voltage resistance, high speed performance, and low loss. For example, Japanese Patent Application Publication No. 2004-88012 (Patent Literature 1) discloses a technique for reducing an amount of hole injection into a cathode region to improve high speed performance and reduce a loss. Specifically, in Patent Literature 1, a thin high-concentration p layer exposed on a surface of a semiconductor substrate and a thick low-concentration p layer exposed on the surface of the semiconductor substrate are alternately disposed in the planar direction of the semiconductor substrate to reduce a dose of p-type impurities in an anode region so as to facilitate a smaller amount of hole injection into a cathode region.

### CITATION LIST

### Patent Literature

Patent Literature 1: Japanese Patent Application Publication No. 2004-88012

### SUMMARY OF INVENTION

### Technical Problem

As described, in Japanese Patent Application Publication No. 2004-88012, if the dose of p-type impurities in the anode region is reduced to facilitate the smaller amount of hole injection into the cathode region, voltage resistance decreases. A depth, an impurity concentration, and the dose of impurities of the anode region are limited, to ensure voltage resistance of a semiconductor device. Conventional semiconductor devices have difficulty in simultaneously facilitating the voltage resistance and the smaller hole injection amount.

### Solution to Problem

A first semiconductor device disclosed by the specification comprises a semiconductor substrate that comprises an anode region and a cathode region. The anode region comprises a first conductivity type first region having a maximum impurity concentration of the first. conductivity type at a position that is at a first depth from a surface of the semiconductor substrate and a first conductivity type second region having a maximum impurity concentration of the first conductivity type at a position that is at a second depth, and on a surface side of the semiconductor substrate than the first depth, and a third region provided between the first region and the second region, and having an impurity concentration of the first conductivity type that is equal to or less than 1/10 (one-tenth) of the surface of the semiconductor substrate.

According to the first semiconductor device, since the third region having a sufficiently low impurity concentration of the first conductivity type is provided between the first region and the second region, an influence of the first region on a hole injection amount can be suppressed. The impurity concentration of the first conductivity type in the first region can be increased to ensure voltage resistance while the impurity of the first conductivity type in the second region can be reduced to suppress the hole injection amount, thereby simultaneously obtaining voltage resistance and a reduction in the hole injection amount.

In the first semiconductor device, the third region may be a region that contains impurities of a second conductivity type. Moreover, at least a part of the third region may be exposed at the surface of the semiconductor substrate, and forms a Schottky junction with a surface electrode of the semiconductor substrate.

In the first semiconductor device, the impurity concentration of the first region at the position at the first depth is preferably equal to or less than 1×10¹⁶ atoms/cm³ (atoms per cubic centimeter).

A second semiconductor device disclosed by the specification comprises a semiconductor substrate that comprises a diode region and an IGBT region. The diode region comprises an anode region and a cathode region. The anode region comprises a first conductivity type first region having a maximum impurity concentration of the first conductivity type at a position that is at a first depth from a surface of the semiconductor substrate and a first conductivity type second region having a maximum impurity concentration of the first conductivity type at a position that is at a second depth, and on a surface side of the semiconductor substrate than the first depth. The IGBT region comprises a first conductivity type body region, a second conductivity type drift region, a second conductivity type emitter region, and a first conductivity type collector region. The body region has a first maximum impurity concentration of the first conductivity type at a position that is at a first depth from the surface of the semiconductor substrate and a second maximum impurity concentration of the first conductivity type at a position on the surface side of the semiconductor substrate than the first depth.

Like the first semiconductor device, the second semiconductor device can increase the impurity concentration of the first conductivity type in the first region to ensure the voltage resistance, and can reduce the impurity of the first conductivity type in the second region to suppress the hole injection amount. Moreover, since the third region having a sufficiently low impurity concentration of the first conductivity type is provided between the first region and the second region, the influence of the first region on the hole injection amount can be suppressed. In the IGBT region, the region having the first maximum value can ensure voltage resistance while the region having the second maximum value allows efficient drawing of holes during an IGBT operation.

### BRIEF DESCRIPTION OF DRAWINGS

FIG. 1 is a plan view of a semiconductor device according to a first embodiment.

FIG. 2 is a cross-sectional view taken along line II-II of FIG. 1.

FIG. 3 is a conceptual diagram of an impurity concentration distribution in an anode region of the semiconductor device shown in FIG. 1.

FIG. 4 is an explanatory drawing of a method of manufacturing the semiconductor device according to the first embodiment.

FIG. 5 is an explanatory drawing of the method of manufacturing the semiconductor device according to the first embodiment.

FIG. 6 is an explanatory drawing of the method of manufacturing the semiconductor device according to the first embodiment.

FIG. 7 is an explanatory drawing of the method of manufacturing the semiconductor device according to the first embodiment.

FIG. 8 is a longitudinal section of a semiconductor device according to a modification.

FIG. 9 is a plan view of the semiconductor device according to the modification.

FIG. 10 is a plan view of a semiconductor device according to a modification.

FIG. 11 is a longitudinal section of a semiconductor device according to a second embodiment.

FIG. 12 is a conceptual diagram of an impurity concentration distribution in an anode region of the semiconductor device shown in FIG. 11.

FIG. 13 is an explanatory drawing of a method of manufacturing the semiconductor device according to the second embodiment.

FIG. 14 is an explanatory drawing of the method of manufacturing the semiconductor device according to the second embodiment.

FIG. 15 is an explanatory drawing of the method of manufacturing the semiconductor device according to the second embodiment.

FIG. 16 is an explanatory drawing of the method of manufacturing the semiconductor device according to the second embodiment.

FIG. 17 is an explanatory drawing of the method of manufacturing the semiconductor device according to the second embodiment.

FIG. 18 is an explanatory drawing of the method of manufacturing the semiconductor device according to the second embodiment.

FIG. 19 is a longitudinal section of a semiconductor device according to a third embodiment.

FIG. 20 is a conceptual diagram of an impurity concentration distribution in an anode region of the semiconductor device shown in FIG. 19.

FIG. 21 is a conceptual diagram of an impurity concentration distribution in and near a body region of the semiconductor device shown in FIG. 19.

FIG. 22 is a longitudinal section of a semiconductor device according to a modification.

### DESCRIPTION OF EMBODIMENTS

### First Embodiment

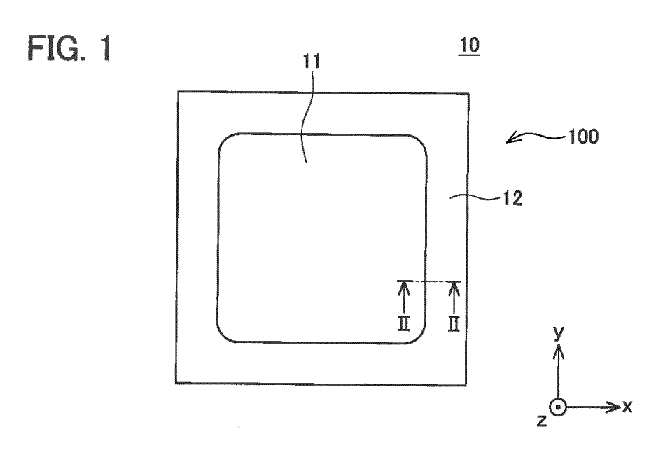

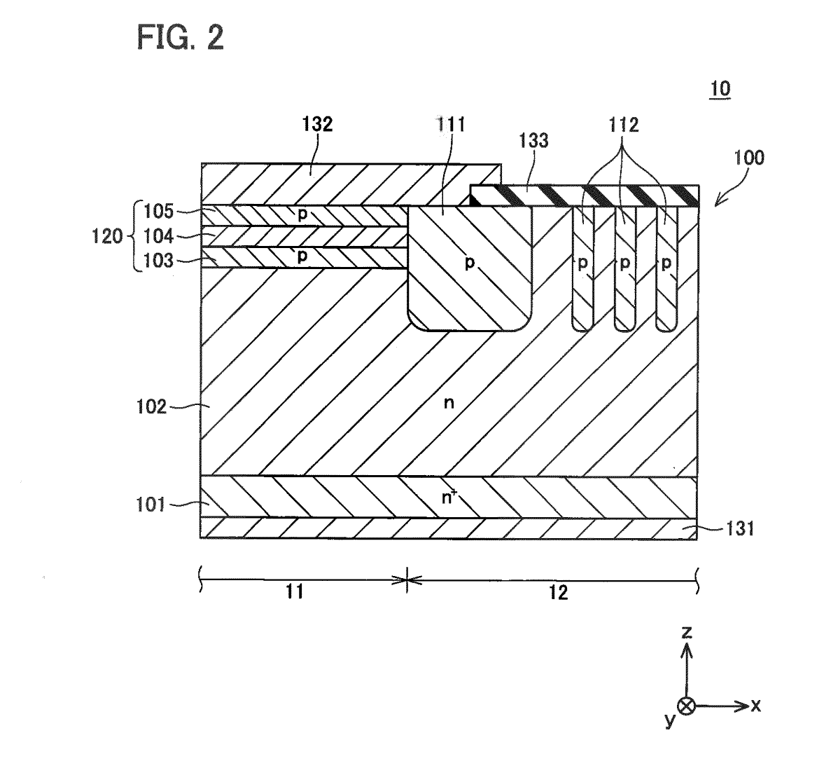

As shown in FIGS. 1 and 2, a semiconductor device 10 includes a semiconductor substrate 100 having a cell region 11 and a peripheral region 12. In FIG. 1, a surface electrode 132 is not illustrated.

The semiconductor substrate 100 includes an n-type cathode layer 101 exposed on a backside (surface on a negative side on the z axis) of the semiconductor substrate 100 and an n-type drift layer 102 provided on a surface (surface on a positive side on the z axis) of the cathode layer 101. The cathode layer 101 and the drift layer 102 constitute a cathode region. The cathode layer 101 is in contact with a backside electrode 131. The cell region 11 includes an anode region 120 provided on a surface of the drift layer 102. The anode region 120 includes a first region 103 in contact with the surface of the drift layer 102, a second region 105 exposed on a surface of the semiconductor substrate 100, and a third region 104 provided between the first region 103 and the second region 105. The second region 105 is in contact with the surface electrode 132. In the peripheral region 12, p-type FLR layers 111 and 112 are provided on the surface of the drift layer 102. A surface of the FLR layer 111 is in contact with the surface electrode 132 on its side closer to the center of the semiconductor substrate 100 and is in contact with an insulating film 133 on its peripheral side. The FLR layers 111 and 112 constitute a peripheral voltage resistance structure of the semiconductor device 10. The pattern of the peripheral voltage resistance structure is not limited to the FLR layers and may be conventionally known structure, e.g., a RESURF layer.

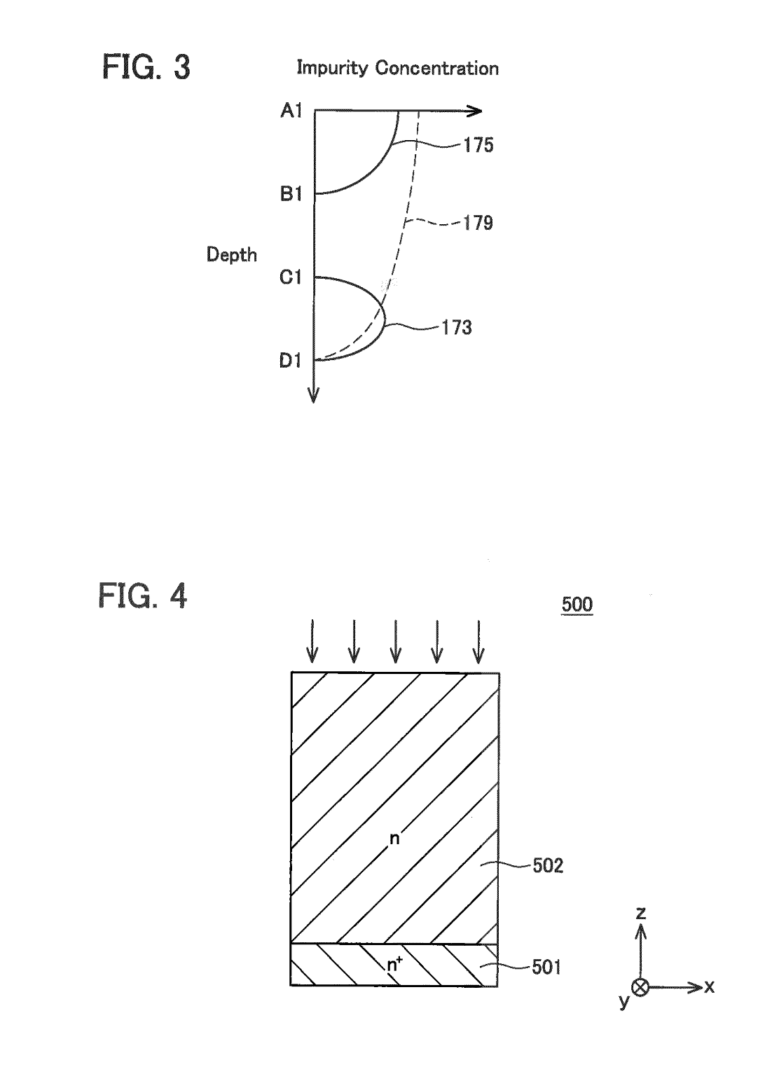

FIG. 3 shows a p-type impurity concentration distribution in the depth direction of the anode region 120. The vertical axis indicates positions in the semiconductor substrate 100 in the depth direction. A1 denotes an upper end position of the second region 105, B1 denotes a position on the boundary between the second region 105 and the third region 104. C1 denotes a position on the boundary between the third region 104 and the first region 103, and D1 denotes a position on the boundary between the first region 103 and the drift layer 102. Reference numerals 173 and 175 indicate a p-type impurity concentration distributions of the first region 103 and the second region 105, respectively. For comparison, reference numeral 179 indicates a p-type impurity concentration distribution of an anode region of a conventional semiconductor device.

The distribution 173 has a maximum p-type impurity concentration at a first depth from the surface of the semiconductor substrate 100, while the distribution 175 has a maximum p-type impurity concentration at a second depth from the surface of the semiconductor substrate 100. The first region 103 has a maximum p-type impurity concentration (the peak concentration of the distribution 173) of 2×10¹⁶ atoms/cm³. The second region has a maximum p-type impurity concentration of 1×10¹⁷ atoms/cm³ on the surface (specifically, at the depth A1) of the semiconductor substrate 100. A p-type impurity concentration of the third region 104 is lower than 1×10¹⁶ atoms/cm³. The p-type impurity concentration of the third region 104 is equal to or less than 1/10 (one-tenth) of the p-type impurity concentration at the depth A1 that is the surface position of the semiconductor substrate 100.

In a conventional semiconductor device, like the distribution 179, a p-type impurity concentration of an anode region exhibits its maximum value at the surface of the semiconductor substrate (at the depth A1) and decreases toward a deeper side in the semiconductor substrate. Thus, in order to ensure the voltage resistance of the semiconductor device, an increase in p-type impurity concentration in a region near the cathode region within the anode region requires a higher p-type impurity concentration at the surface of the semiconductor substrate. An increase in p-type impurity concentration on the surface of the semiconductor substrate requires hole injection in larger amount. This brings forth deterioration in the high speed performance and the low-loss performance of the semiconductor device.

In the semiconductor device 10, in contrast, the distribution 173 of p-type impurity concentration in the first region 103 and the distribution 175 of p-type impurity concentration of the second region 105 can be separately and independently designed. Only the p-type impurity concentration of the first region 103 needs to be properly increased to increase voltage resistance, whereas the p-type impurity concentration of the second region 105 does not need to be increased. This can sufficiently reduce the p-type impurity concentration of the second region 105, thereby suppressing the hole injection amount. Moreover, the semiconductor device 10 includes the third region 104 having a low p-type impurity concentration between the first region 103 and the second region 105. This can suppress the influence of the p-type impurity of the first region 103 on the hole injection amount. As described in the present embodiment, if the p-type impurity concentration of the third region 104 is equal to or less than 1/10 (one-tenth) of the p-type impurity concentration at the depth A1 that is the surface position of the semiconductor substrate 100, the influence of the p-type impurity concentration of the first region 103 on the hole injection amount can be suppressed.

Referring to FIGS. 4 to 6, a method of manufacturing the semiconductor device 10 will be described below. FIGS. 4 to 6 only show the cell region 11 of FIG. 2. Only a process for forming the anode region 120 in the cell region 11 will be described below with reference to these drawings. Other configurations of the semiconductor device 10 can be formed by the same method as a conventional semiconductor device.

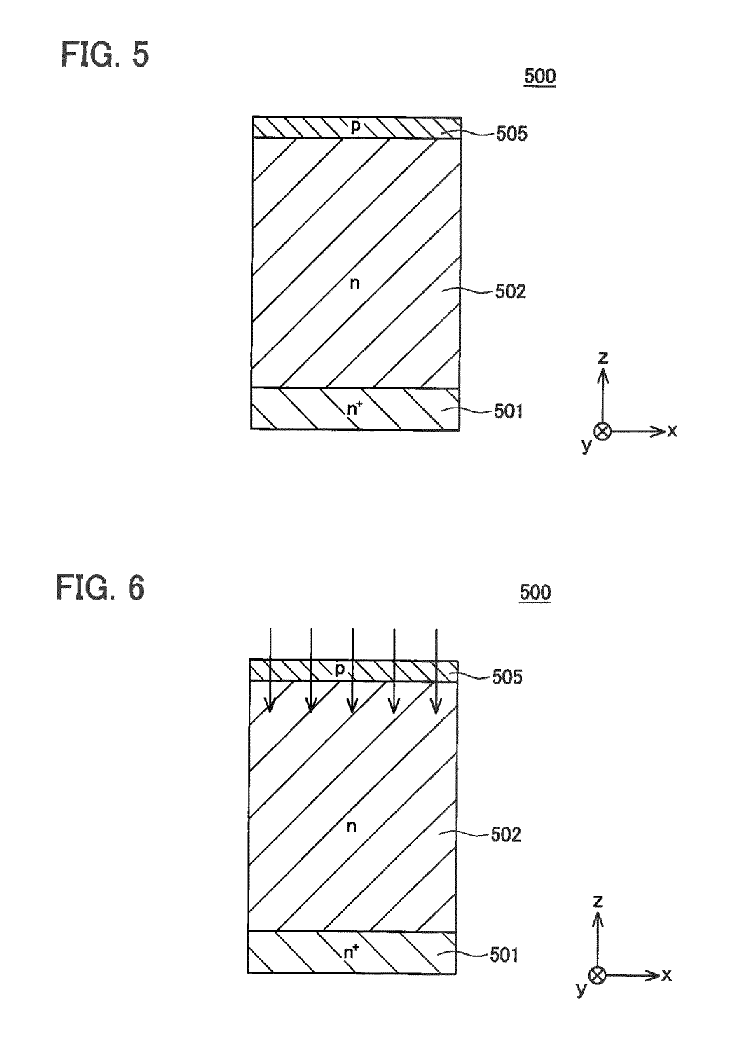

First, as shown in FIG. 4, a semiconductor substrate 500 is prepared. The semiconductor substrate 500 includes an n⁺ layer 501 serving as the cathode layer 101 and an n layer 502 serving as the drift layer 102. The n⁺ layer 501 and the n layer 502 are sequentially stacked from a backside of the semiconductor substrate 500. In this state, as shown in FIG. 4, p-type impurity ions are implanted from the surface of the semiconductor substrate 500 to a position at the second depth in the n layer 502. The second depth is substantially located on the surface of the semiconductor substrate 500. Thus, as shown in FIG. 5, a p-type ion implantation layer 505 is formed. The n⁺ layer 501 may be formed in the semiconductor substrate 500 after the step of forming the surface structure of the semiconductor device 10, as will be discussed below.

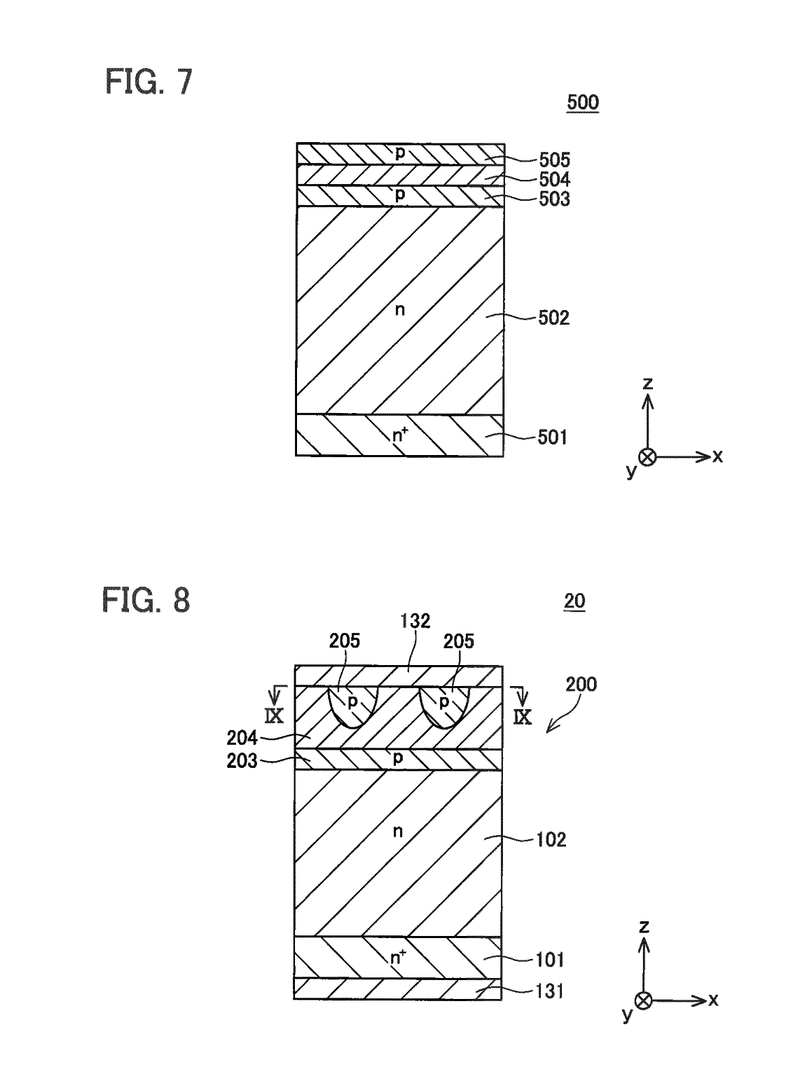

Subsequently, as shown in FIG. 6, p-type impurity ions are implanted from the surface of the semiconductor substrate 500 to a position at the first depth in the n layer 502. As shown in FIG. 7, a p-type ion implantation layer 503 is formed. The first depth is deeper than the second depth (a negative position on the z axis). Furthermore, an intermediate layer 504 having a low p-type impurity concentration is formed between the ion implantation layer 503 and the ion implantation layer 505. The semiconductor substrate 500 in FIG. 7 is annealed so as to manufacture, as shown in FIG. 2, the semiconductor device 10 having the anode region 120 including the first region 103, the second region 105, and the third region 104.

### (Modification)

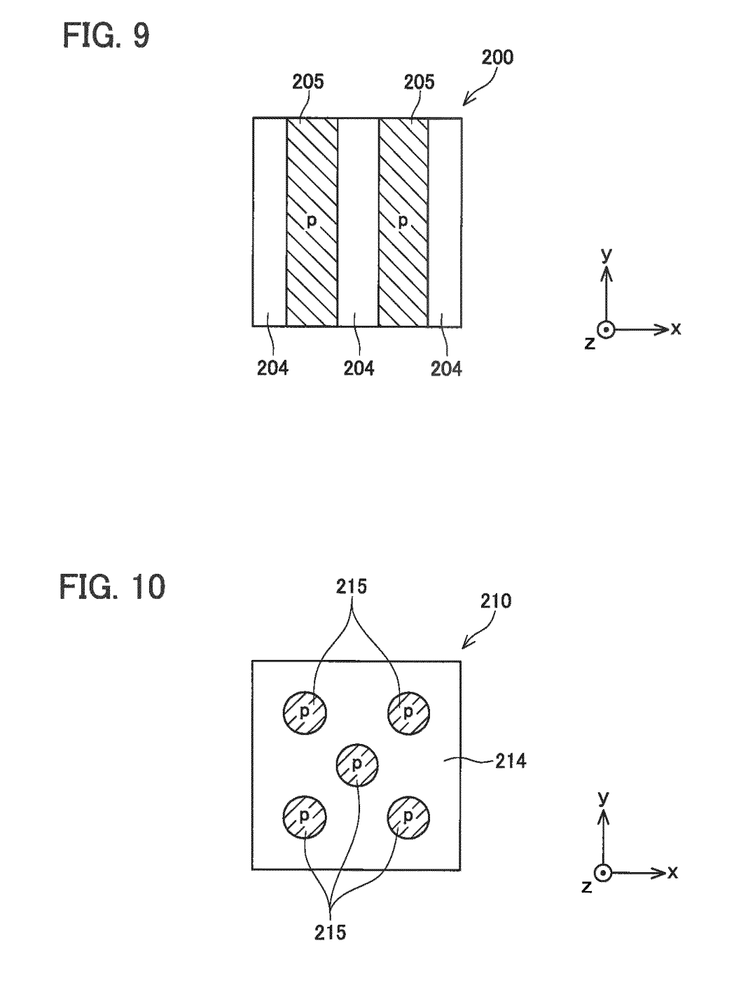

In the first embodiment, the second region 105 covers the entire surface of the third region 104. The present invention is not limited to this configuration. For example, as in a semiconductor device 20 shown in FIGS. 8 and 9, a cell region may include second regions 205 partially formed on the surface of a third region 204. The second regions 205 are shaped like stripes extending in a y direction on a surface of a semiconductor substrate 200 in plan view. On the surface of the semiconductor substrate 200, the second regions 205 and the third regions 204 are exposed in contact with the surface electrode 132. Each of the second region 205 and the surface electrode 132 form an ohmic junction while the third region 204 and the surface electrode 132 form a Schottky junction. As shown in FIG. 10, on a surface of a semiconductor substrate 210 in plan view, circular second regions 215 may be distributed on a surface of a third region 214.

### Second Embodiment

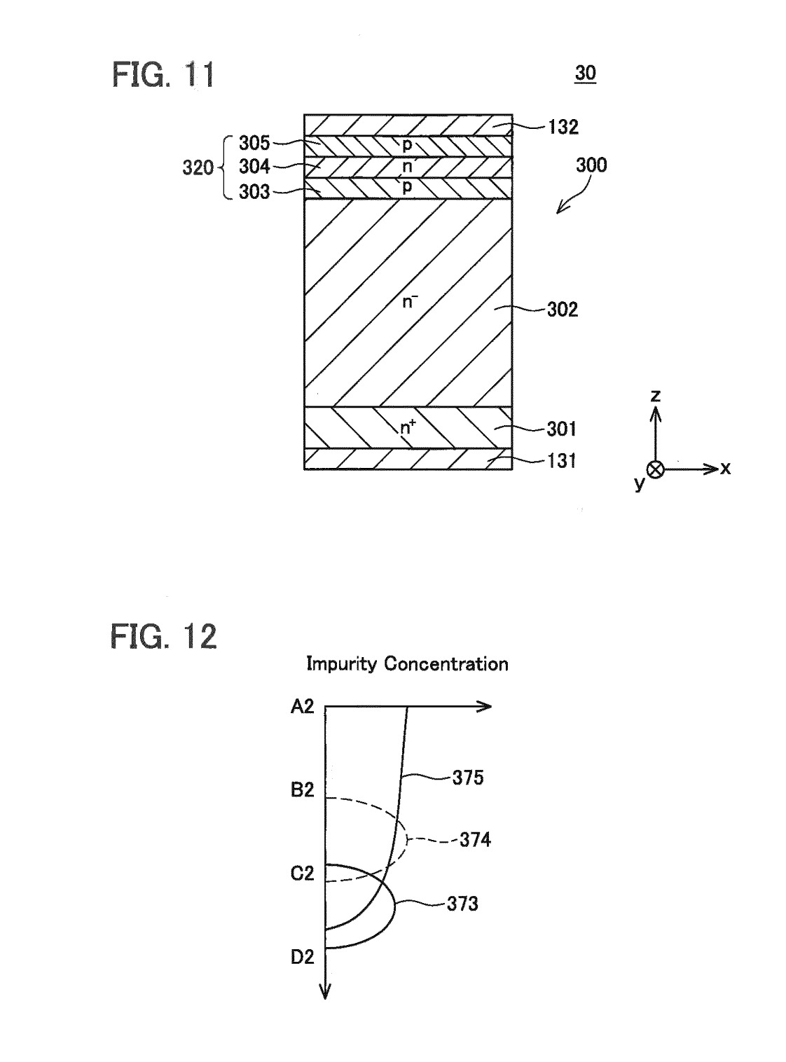

FIG. 11 is a longitudinal section showing a cell region of a semiconductor device 30 according to a second embodiment. The semiconductor device 30 includes a semiconductor substrate 300. The semiconductor substrate 300 includes an n-type cathode layer 301, an n-type drift layer 302, a p-type first region 303, an n-type third region 304, and a p-type second region 305 that are sequentially stacked from a backside of the semiconductor substrate 300. The cathode layer 301 and the drift layer 302 constitute a cathode region. The first region 303, the third region 304, and the second region 305 constitute an anode region 320. The cathode layer 301 is in contact with the backside electrode 131 while the second region 305 is in contact with the surface electrode 132. Other configurations of the semiconductor device 30 are identical to those of the semiconductor device 10 shown in FIG. 1 and thus the explanation thereof is omitted.

FIG. 12 shows an impurity concentration distribution in the depth direction of the anode region 320. The vertical axis indicates a position of the semiconductor substrate 300 in the depth direction. A2 denotes an upper end position of the second region 305, B2 denotes a position on the boundary between the second region 305 and the third region 304, C2 denotes a position on the boundary between the third region 304 and the first region 303, and D2 denotes a position on the boundary between the first region 303 and the drift layer 302. Reference numerals 373 and 375 indicate a p-type impurity concentration distributions of the first region 303 and the second region 305, respectively. Reference numeral 374 indicates a n-type impurity concentration distribution of the third region 304.

The distribution 373 has a maximum p-type impurity concentration at a first depth (between the depths C2 and D2) from the surface of the semiconductor substrate 300, and a curve indicating the concentration distribution thereof substantially extends into the first region 303. The distribution 375 has a maximum p-type impurity concentration at a second depth (a depth A1 in the present embodiment) from the surface of the semiconductor substrate 300, and a curve indicating the concentration distribution thereof extends until the first region 303. The distribution 374 has a maximum n-type impurity concentration at a third depth (between the depths B2 and C2) from the surface of the semiconductor substrate 300, and a curve indicating the concentration distribution thereof substantially extends into the third region 304.

The first region 303 has a maximum p-type impurity concentration (the peak concentration value of the distribution 373) of 2×10¹⁶ atoms/cm³. A p-type impurity concentration of the second region 305 has a maximum value of 1×10¹⁷ atoms/cm³ on the surface (specifically, at the depth A2) of the semiconductor substrate 300. A p-type impurity concentration of the third region 304 is lower than 1×10¹⁶ atoms/cm³. The p-type impurity concentration of the third region 304 is equal to or less than 1/10 (one-tenth) of the p-type impurity concentration at the depth A2 that is the surface position of the semiconductor substrate 300.

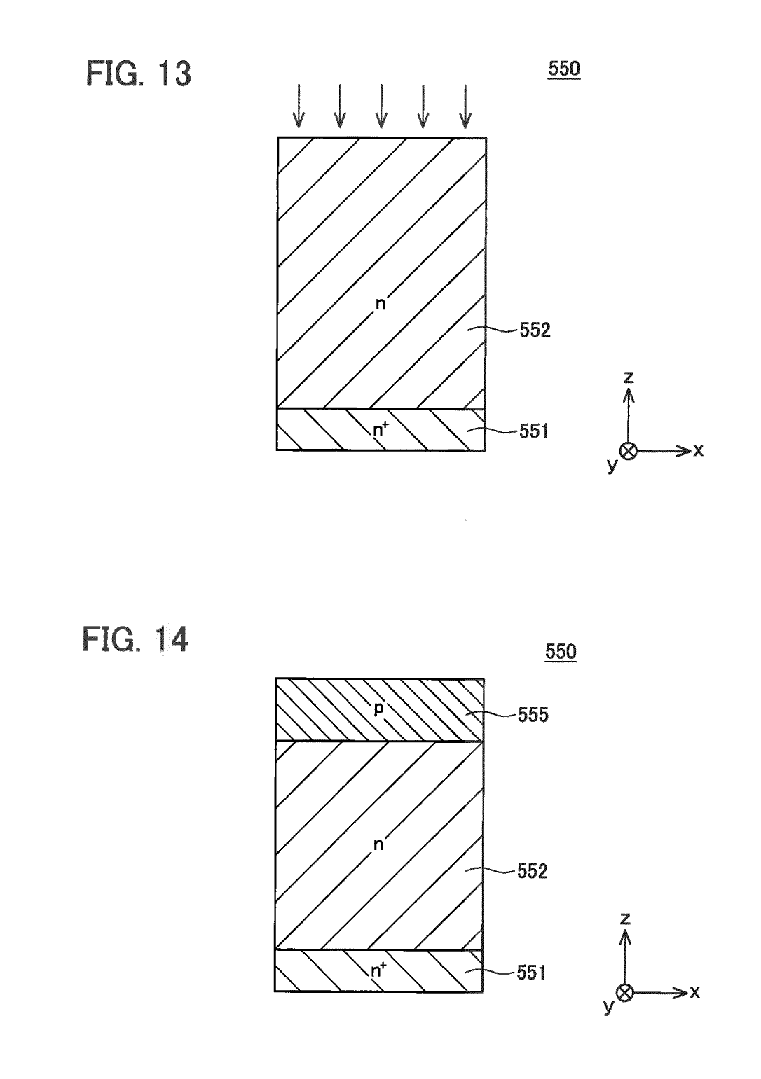

Referring to FIGS. 13 to 18, a method of manufacturing the semiconductor device 30 will be described below. First, as shown in FIG. 13, a semiconductor substrate 550 is prepared. The semiconductor substrate 550 includes an n⁺ layer 551 serving as the cathode layer 301 and an n layer 552 serving as the drift layer 302. The n⁺ layer 551 and the n layer 552 are sequentially stacked from the backside of the semiconductor substrate 550. In this state, as shown in FIG. 13, p-type impurity ions are implanted from the surface of the semiconductor substrate 550 to a position at the second depth in the n layer 552. The second depth is substantially located on the surface of the semiconductor substrate 550. Thus, as shown in FIG. 14, a p-type ion implantation layer 555 is formed.

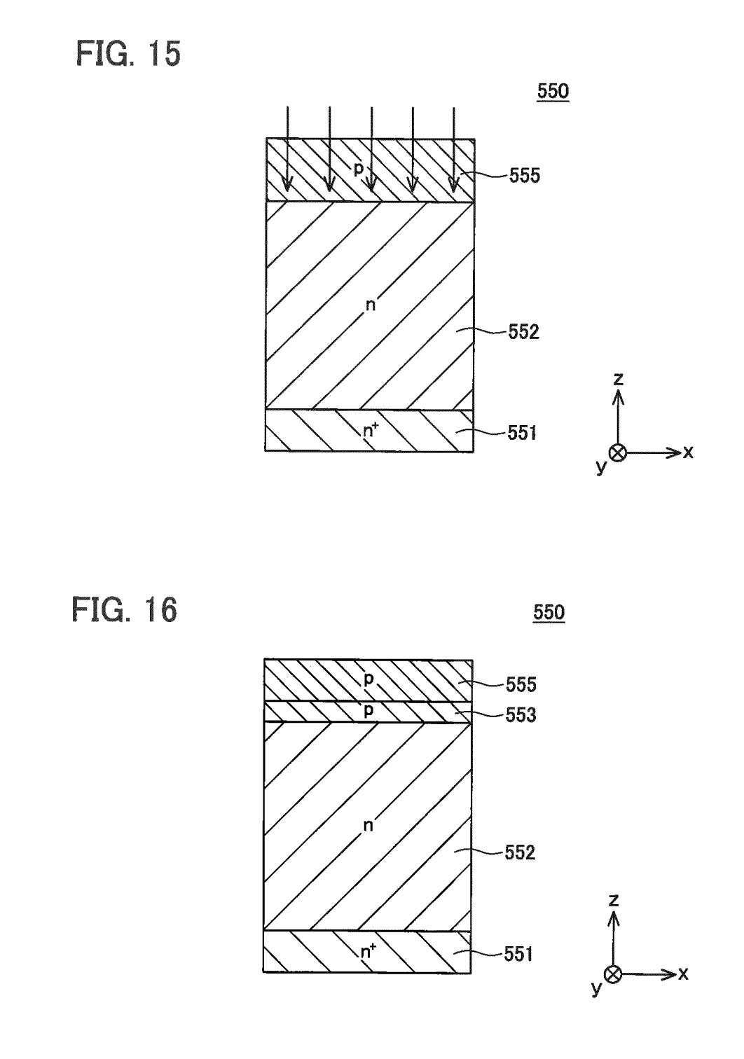

Subsequently, as shown in FIG. 15, p-type impurity ions are implanted from the surface of the semiconductor substrate 550 to a position at the first depth in the ion implantation layer 555. As shown in FIG. 16, a p-type ion implantation layer 553 is formed. The first depth is deeper than the second depth (a negative position on the z axis).

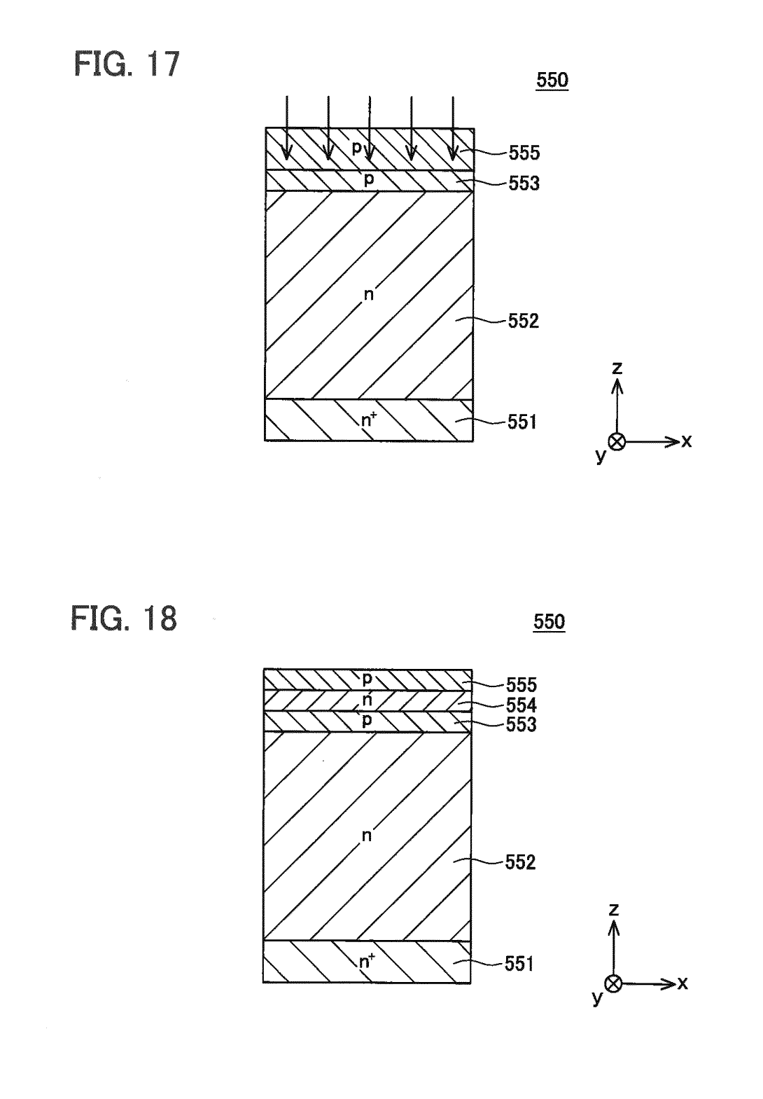

After that, as shown in FIG. 17, n-type impurity ions are implanted between the first depth and the second depth in the ion implantation layer 555. As shown in FIG. 18, an n-type ion implantation layer 554 is formed. The semiconductor substrate 550 in FIG. 18 is annealed so as to manufacture, as shown in FIG. 11, the semiconductor device 30 having the anneal layer 320 including the first region 303, the second region 305, and the third region 304.

As described in the present embodiment, the third region 304 may be formed by n-type ion implantation. In this case, the distribution of the p-type impurity concentration having a maximum value in the second region 305 may spread over the anode region 320 as indicated by the distribution 375.

### Third Embodiment

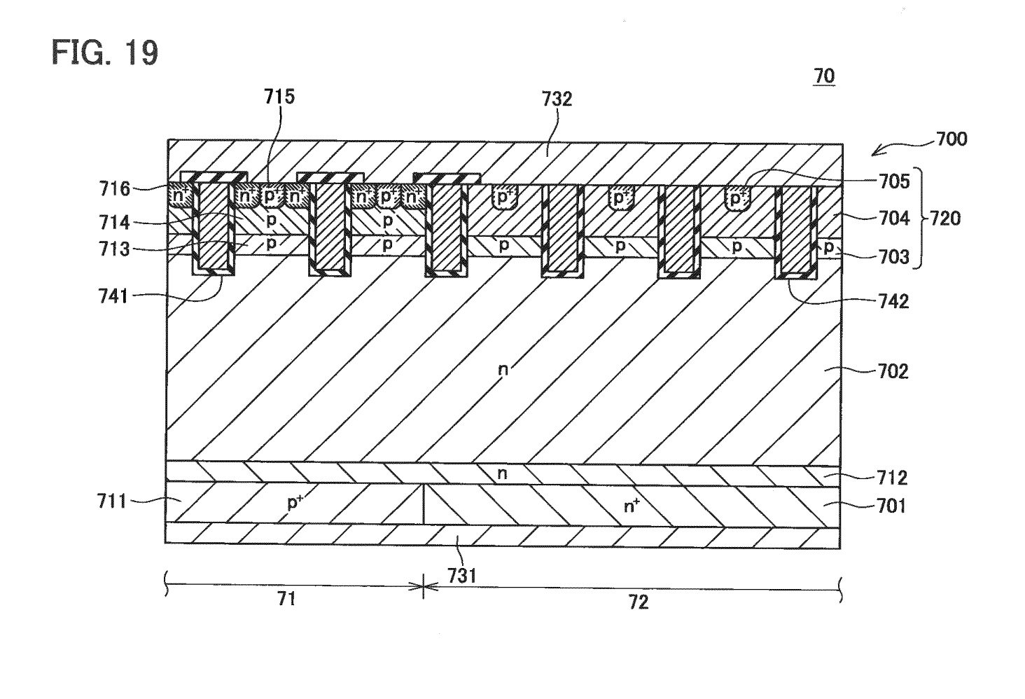

FIG. 19 is a longitudinal section showing a cell region of a semiconductor device 70 according to a third embodiment. The semiconductor device 70 includes a semiconductor substrate 700 having an IGBT region 71 and a diode region 72. The IGBT region 71 of the semiconductor substrate 700 includes a p-type collector layer 711, an n-type buffer layer 712, an n-type drift layer 702, a p-type first body layer 713, and a p-type second body layer 714 that are sequentially stacked from a backside of the semiconductor substrate 700. P-type body contact layers 715 and n-type emitter layers 716 are formed on a surface of the second body layer 714 and are exposed on a surface of the semiconductor substrate 700. The buffer layer 712 and the drift layer 702 are extended to the diode region 72. The semiconductor substrate 700 includes trench gates 741 that reach the drift region 702 through the first body layer 713 and the second body layer 714. Each of the side of the trench gates 741 is in contact with the corresponding emitter layer 716. The first body layer 713, the second body layer 714, and the body contact layer 715 act as a body region in the IGBT region 71.

The diode region 72 includes an n-type cathode layer 701, the buffer layer 712, the drift layer 702, a p-type first region 703, and an n-type third region 704 that are sequentially stacked from the backside of the semiconductor substrate 700. P-type second regions 705 are formed at a part of the surface of the third region 704 and are exposed on the surface of the semiconductor substrate 700. A cathode region of the diode region 72 includes the cathode layer 701, the buffer layer 712, and the drift layer 702. The anode region 720 includes the first region 703, the second region 705, and the third region 704. The semiconductor substrate 700 includes dummy gates 742 that reaches the drift region 702 through the second region 704 and the first region 703.

The second region 705, the third region 704, the body contact layer 715, and the emitter layer 716 are in contact with a surface electrode 732. The cathode layer 701 and the collector layer 711 that are adjacent to each other are exposed on the backside of the semiconductor substrate 700 and are in contact with a backside electrode 731.

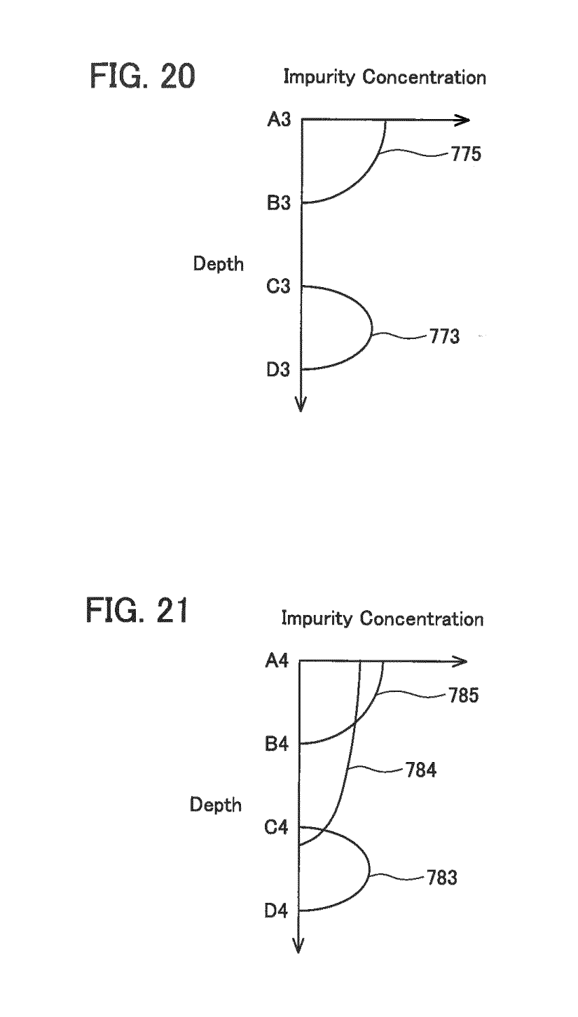

FIG. 20 shows a p-type impurity concentration distribution in the depth direction of the anode region 720. The vertical axis indicates positions in the semiconductor substrate 700 in the depth direction. A3 denotes an upper end position of the second region 705, B3 denotes a lower end position of the second region 705, C3 denotes a position on the boundary between the third region 704 and the first region 703, and D3 denotes a position on the boundary between the first region 703 and the drift layer 702. Reference numerals 773 and 775 indicate a p-type impurity concentration distributions of the first region 703 and the second region 705, respectively.

FIG. 21 shows a p-type impurity concentration distribution from the body contact layer 715 to the first body layer 713 in the depth direction. The vertical axis indicates a position of the semiconductor substrate 700 in the depth direction. A4 denotes an upper end position of the body contact layer 715, B4 denotes a lower end position of the body contact layer 715, C4 denotes a position on the boundary between the second body layer 714 and the first body layer 713, D4 denotes a position on the boundary between the first body layer 713 and the drift layer 702. Reference numerals 783, 784, and 785 indicate a p-type impurity concentration distributions of the first body layer 713 and the second region 705. The distribution 775 and the distribution 785 may be formed in the same step. The distribution 773 and the distribution 783 may be formed in the same step. As shown in FIG. 21, the body region of the IGBT region 71 has a first maximum p-type impurity concentration (the maximum value of the distribution 783) at a position that is a first depth from the surface of the semiconductor substrate 700 and a second maximum p-type impurity concentration (the maximum value of the distribution 775) at a position on the surface side of the semiconductor substrate 700 than the first depth. A region having a relatively low p-type impurity concentration is provided between the region having the first maximum value and the region having the second maximum value.

As described in the present embodiment, the semiconductor device may contain a semiconductor element structure other than diodes. The semiconductor device 70 is an RC-IGBT that includes the IGBT region 71 and the diode region 72 in the same semiconductor substrate 700. In the RC-IGBT, the drift layer 702 in the diode region 72 may include a life-time control region (e.g., a region formed with a high concentration of crystal defects by ion irradiation and so on) to reduce carrier life time so as to improve switching characteristics. The semiconductor device 70 can reduce a hole injection amount from the anode region to the cathode region in the diode region 72, thereby suppressing the life-time control function of the life-time control region. Since the life-time control function is suppressed, a deterioration in the characteristics of the IGBT region 71 by the life-time control region can be reduced, leading to a smaller leak current. In the IGBT region 71, voltage resistance is ensured in the region (the first body layer 713) having the first maximum value. In the region (body contact layer 715) having the second maximum value, holes can be efficiently drawn during an IGBT operation. An adjustment to the impurity concentration of the region (second body layer 714) between the region having the first maximum value and the region having the second maximum value allows n-type channel control along each of the trench gates 741 during an IGBT operation.

### (Modification)

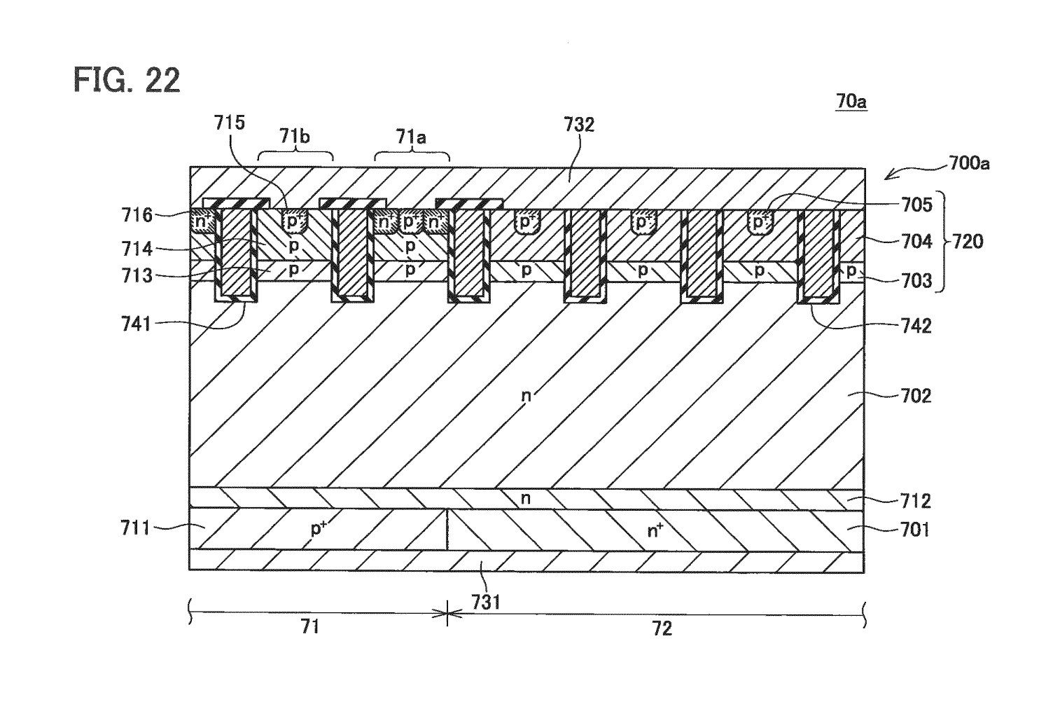

The configuration of the IGBT region is not limited to that of the third embodiment. For example, like a semiconductor device 70a shown in FIG. 22, an IGBT region 71 of a semiconductor substrate 700a may include a region 71a containing an emitter layer 716 and a region 71b not containing an emitter layer 716. In the region 71b, a channel is not formed upon gate-on, reducing a channel density in the IGBT region 71. Thus, carriers can be accumulated so as to reduce an on resistance in the semiconductor device 70a.

The embodiments of the present invention have been described above in detail. However, the embodiments are illustrative and do not limit the claims. The technique described in the claims includes the illustrated specific examples to which many variations and changes are made.

Technical elements described herein or in the drawings are technically useful either solely or in combination and are not limited to the combinations set forth in the claims at the time of filing. Furthermore, the technique illustrated herein or in the drawings simultaneously achieves a plurality of purposes and provides technical usefulness by accomplishing one of the purposes.

1-7. (canceled)

8. A semiconductor device comprising a semiconductor substrate that comprises an anode region and a cathode region, wherein
the anode region comprises:
a first conductivity type first region having a peak impurity concentration of the first conductivity type at a position that is at a first depth from a surface of the semiconductor substrate;
a first conductivity type second region having a maximum impurity concentration of the first conductivity type at a position that is at a second depth, and on a surface side of the semiconductor substrate than the first depth; and
a third region provided between the first region and the second region, and having an impurity concentration of the first conductivity type that is equal to or less than 1/10 (one-tenth) of the surface of the semiconductor substrate.

9. A semiconductor device of claim 8, wherein
an impurity concentration of the first conductivity type of the third region is lower than any of the impurity concentration of the first conductivity type at the position that is at the first depth of the first region and the impurity concentration of the first conductivity type at the position that is at the second depth of the second region.

10. A semiconductor device of claim 8, wherein
the third region is a region that contains impurities of a second conductivity type.

11. A semiconductor device of claim 10, wherein
at least a part of the third region is exposed at the surface of the semiconductor substrate, and forms a Schottky junction with a surface electrode of the semiconductor substrate.

12. A semiconductor device of claim 8, wherein
the impurity concentration of the third region is equal to or less than 1×10¹⁶ atoms/cm³ (atoms per cubic centimeter).

13. A semiconductor device comprising a semiconductor substrate that comprises a diode region and an IGBT region, wherein
the diode region comprises an anode region and a cathode region,
the anode region comprises:
a first conductivity type first region having a maximum impurity concentration of the first conductivity type at a position that is at a first depth from a surface of the semiconductor substrate; and
a first conductivity type second region having a maximum impurity concentration of the first conductivity type at a position that is at a second depth, and on a surface side of the semiconductor substrate than the first depth, the IGBT region comprises:
a first conductivity type body region;
a second conductivity type drift region;
a second conductivity type emitter region; and
a first conductivity type collector region, and
the body region has:
a first maximum impurity concentration of the first conductivity type at a position that is at the first depth from the surface of the semiconductor substrate; and
a second maximum impurity concentration of the first conductivity type at a position on the surface side of the semiconductor substrate than the first depth.

14. A semiconductor device comprising a semiconductor substrate that comprises an anode region and a cathode region, wherein
the anode region comprises:
a first conductivity type first region which is formed by a first ion implantation process to have a peak impurity concentration of a first conductivity type at a position that is at a first depth from a surface of the semiconductor substrate;
a first conductivity type second region which is formed by a second ion implantation process to have a maximum impurity concentration of the first conductivity type at a position that is at a second depth from the surface of the semiconductor substrate;
a third region provided between the first region and the second region, and having a impurity concentration of the first conductivity type that is equal to or less than 1/10 (one-tenth) of the surface of the semiconductor substrate.
